(19) United States
(12) Patent Application Publication
(10) Pub. No.: US 2001/0047737 A1
(43) Pub. Date: Dec. 6, 2001

(54) Method of pretreating articles for brazing and coating material therefor

(76) Inventor: Michael K. Levenson, Rancho Palos, CA (US)

Correspondence Address: Joseph H. Roediger, Ste. 212, 3333 E. Camelback Rd., Phoenix, AZ, 85018, US

(21) Appl. No.: 09/862,567

(22) Filed: May 22, 2001

Related U.S. Application Data
(60) Provisional application No. 60/206,642, filed on May 24, 2000.

(51) Int. Cl. B05D 3/02; C23C 16/00

(52) U.S. Cl. 106/1.19; 427/383.1; 427/385.5

(57) ABSTRACT

The method of precoating surfaces to be brazed without the use of corrosive flux by the application of a mixture of silver particulates, binder and solvent followed by solvent evaporation and heating for depolymerization of the binder. The heating results in a silver film formed on the surface prior to brazing.

### CROSS REFERENCE TO RELATED APPLICATION

The present invention is based on provisional patent application Ser. No. 60/206,642 filed May 24, 2000.

This invention relates to a method of brazing by the application of a metallic coating to the articles prior to application of the brazing alloy, and the composition of the coating material therefor.

### BACKGROUND OF THE INVENTION

The effectiveness of a method of connecting articles by thermally melting an alloy with a melting point lower than that of the material of the articles so that the molten alloy fills the gaps between the parts and covers the adjacent surfaces is determined in part by the wettability of the brazing alloy and the presence of an oxidation coating on the articles. The presence of an oxidation coating on one or both articles to be joined normally requires a corrosive flux to be applied to the material with cleaning steps performed after the brazing to remove residual flux.

The removal of flux from the work piece often involves the disposal and treatment of toxic materials that are deleterious to the environment. Further removal of the flux is needed to provide an aesthetic product. For these reasons the development of a brazing process that can be performed without the need for fluxes is a recognized goal. In addition to the problems associated with the handling of toxic and corrosive materials, fluxes tend to obscure the areas to be brazed, thus hindering precision during the brazing process.

Attempts have been made to eliminate the need for flux in a brazing process by conducting the process in an oxygen-free atmosphere. In the case of brazing to aluminum, the application of resins as a protective coating for the aluminum has been proposed as shown for example in U.S. Pat. No. 3,937,387. Prior to brazing, the application of heat is employed to thermally remove the resin in an oxygen-free environment, e.g. purging the heating chamber and filling it with nitrogen.

The present invention is directed to the provision of a method for performing fluxless brazing without requiring a controlled oxygen-free environment and to a pretreatment coating which provides the wettability for the brazing alloy and oxide protection for the articles being brazed. The coating can be applied to the articles by a direct method of application, such as by brush. The use of this novel coating enables brazing to be carried out with a conventional oxyacetylene torch. Thus, the subject invention provides a simplified method of brazing.

### SUMMARY OF INVENTION

The present method of preparing articles for brazing utilizes a metallic coating for application to the articles which coating is a mixture of three components: precious metal particulates, a binder and a solvent for the binder.

After the surfaces of the articles to be brazed are cleaned, the portions of the surfaces of the articles to receive the brazing alloy are coated with the metallic paint. Next, the solvent is permitted to evaporate so that the metal particles and binder form a film on the surfaces. Heat is then applied to depolymerize the binder leaving a metallic layer on the surfaces. The heat can be applied by a torch with a modest flame moving evenly across the surface rather than a vigorous flame which would disturb the distribution of the metallic layer on the surfaces. After the metallic layer is formed, the brazing operation takes place normally using the torch and brazing rod at higher temperature. The brazing alloy wets the molten silver, dissolves the silver and deposits on the surfaces to effect the bond between the brazed articles.

The process takes place without the application of the corrosive flux to the surfaces presumably because of the masking effect of the metallic layer which retards the formation of oxidation products during the high temperatures used in depositing the brazing alloy on the work surfaces. It is to be noted that the process takes place in the ambient atmosphere using the conventional oxy-acetylene torch. The application of the three component mixture can be carried by a brush applicator or spray equipment can be used if desired.

Further features and advantages of the invention will become more readily apparent from the following description of a preferred embodiment of the pretreatment coating and the method of conditioning the articles to be brazed.

### DESCRIPTION OF THE PREFERRED EMBODIMENT

In the practice of the method of the present invention, the surfaces of the articles to be brazed are cleaned in accordance with the standard practices. Since the articles are commonly formed of oxidizable materials, the oxides formed are removed either mechanically or chemically and a degreasing compound is applied. Following these steps, the application of the metallic paint to the surfaces which are to receive the brazing alloy takes place. These surfaces include not only the planar exposed surfaces but also any voids in the region where the adjacent articles are to be in contact.

The surfaces are coated by brush or spray with a metallic paint formed by mixing metal particulates, a binder and a solvent. The thickness of the coating and whether it is applied by one application or by successive applications is determined primarily by the weight percent of the metal particles in the paint. In applications using silver-based paint, the range of weight percent of silver is 10 to 70 percent. Silver paint formulations that have a higher silver content are found to result in a metal layer that requires excessive heating with a torch in order to prepare the articles for brazing. The application of a vigorous high temperature flame from the torch is found to disturb the uniformity of the formed metal layer and adversely affect the resultant bond between articles.

The practical limit on the lower end of the compositional range had been found to be 10 weight percent of silver at which point the viscosity of the metallic paint prevents effective coating of the surfaces which are to later encounter the brazing alloy. Consequently, the brazing alloy does not adequately flow to all areas.

The particulate geometry of the metal used in the present method is preferably flakes due to the area to weight ratio. However, spheres and partially distorted spheres may be used. The particle size is preferably as small as practical with an upper limit of average particle size of 10 microns found acceptable in providing coverage by the final metal layer on the article surfaces.

The binder employed is required to dissolve in the solvent used and must be capable of decomposing into the gaseous state at a suitable temperature during the subsequent steps of the method. The molecular weight of the binder used is important for it controls the degree of solubility of the binder in the solvent and the viscosity of the solution so formed. Also, the molecular weight determines the ease or difficulty of the binder as it first undergoes softening or melting and then thermal depolymerization to evolve in the gaseous state. The gaseous products evolving from the binder do so gently without disturbing the adhesion of the resultant formed layer on the article surfaces. In testing, it has been found that binders having molecular weights in excess of 100,000 exhibit excessive pressure buildup during depolymerization and unduly disturb the formation of an acceptable metal layer.

The polyacrylate and polymethacrylate binders have been found to provide acceptable results. These binders are soluble in a number of solvents, thermally depolymerize into the gaseous state and do not provide an unusually high viscosity mixture. The preferred binder is polymethylmethacrylate having a molecular weight of 15,000 and good solubility in butyl acetate. While the solvent used in the present invention may be selected from a broad group of organic materials including esters, alcohols, ethers and ketones, taken alone or in combination, butyl acetate is a particularly useful solvent for the subject method.

As stated, the composition of the metallic paint is determined in part by the molecular weight of the binder which affects the viscosity of the mixture and the amount of the metal particulate matter. An approximate formulation for use with fine silver flake of 40 weight percent is solvent of 40 weight percent and binder of 20 weight percent. The proportions stated are for a silver paint formulation using polymethylmethacrylate having a molecular weight of 15,000. The solvent is butyl acetate. When the molecular weight of the binder was increased to 100,000, the weight percent of the binder was reduced to 4.8 percent, the solvent was increased to 43.0 weight percent and the amount of silver flake was adjusted to 52.2 weight percent. In the latter formulation, extreme care had to exercised to avoid damage to the resultant silver film.

In the practice of the present invention, the metallic paint mixture is applied to the surfaces of the articles to be brazed. The application can be by brush or by sprayer. Then, the solvent is permitted to evaporate leaving the binder and metal particulate matter in place. Typically, the evaporation of the solvent takes approximately 5 minutes.

Following evaporation, the flame from a torch is used to heat the binder-metal film to a temperature of about 260° c. fo r approximately 2 to 10 seconds to depolymerize the binder and drive it off. Next, a more vigorous flame is used for about 2 to 5 seconds to heat the metal to a glossy film. At this point, the brazing operation commences with the brazing rod being brought into contact with the surfaces and the temperature of the torch being elevated accordingly.

In practice, the torch flame can be directed from any practical angle. However, as the molecular weight of the binder increases, the angle of the torch flame is increased towards 90 degree to the surface. The pressure of the torch flame is then used to prevent the polymerizing high molecular weight binder from causing the metal to lift from the surface of the article. For the mixture using a binder with a molecular weight of 100,000, it was found necessary to orient the torch flame so as to remain perpendicular to the work surface.

While the foregoing description has referred to a specific embodiment of the invention, it is to be noted that modifications and variations may be made therein without departing from the scope of the invention as claimed.

What is claimed is:

1. A method of preparing a material surface for brazing which comprises the steps of:
a) applying a fluid mixture of silver particulates, binder and solvent to the material surface;
b) evaporating the solvent to form a film on the material surface, and
c) heating the film to cause the binder to enter the gaseous state whereby the material surface is provided with a coating of silver.

2. The method according to claim 1 wherein the silver particulates have an average particle size of less than 10 microns.

3. The method according to claim 2 wherein silver is present in the mixture within the range of 10 to 70 weight percent.

4. The method according to claim 3 wherein the silver particulates have a flake geometry.

5. The method according to claim 1 wherein the binder has a molecular weight of less than 100,000.

6. The method according to claim 5 wherein the binder has a molecular weight of about 15,000.

7. The method according to claim 5 wherein the binder is selected from the group consisting of polyacrylates and polymethacrylates.

8. The method according to claim 7 wherein the solvent provides solvency for polyacrylates and polymethacrylates.

9. The method according to claim 8 wherein the binder is polymethylmethacrylate.

10. The method according to claim 9 wherein the solvent is butyl acetate.

11. A coating mixture for preparing a surface for brazing which comprises:
a) a solvent;
b) a binder dissolved in the solvent, and
c) silver particulates added to the solvent.

12. The coating mixture according to claim 11 wherein said silver particulates are present within the range of 10 to 70 weight percent of the mixture.

13. The coating mixture according to claim 12 wherein the silver particulates have an average particle size of less than 10 microns.

14. The coating mixture according to claim 13 wherein the silver particulates have a flake geometry.

15. The coating mixture according to claim 14 wherein the binder has a molecular weight of less than 100,000.

16. The coating mixture according to claim 15 wherein the binder has a molecular weight of about 15,000.

17. The coating mixture according to claim 16 wherein the binder is selected from the group consisting of polyacrylates and polymethacrylates.

18. The coating mixture according to claim 17 wherein the binder is polymethylmethacrylate.

19. The coating mixture according to claim 18 wherein the solvent is butyl acetate.
